(19) United States
(12) Patent Application Publication
(10) Pub. No.: US 2012/0056516 A1
(43) Pub. Date: Mar. 8, 2012

(54) SERVER RACK

(75) Inventor: CHEN-LU FAN, Tu-Cheng (TW)

(73) Assignee: HON HAI PRECISION INDUSTRY CO., LTD., Tu-Cheng (TW)

(21) Appl. No.: 13/089,495

(22) Filed: Apr. 19, 2011

(30) Foreign Application Priority Data
Sep. 7, 2010 (CN) 201010274585.8

(51) Int. Cl. H05K 5/02

(52) U.S. Cl. 312/223.2

(57) ABSTRACT

A server rack comprises two side plates, a shell and a locking member. The two side plates respectively define a through hole; the shell secures the side plate, which includes a maintaining member located between the two side plates; the locking member secured to the maintaining member including a locking tongue. The locking tongue includes a body and two positioning pieces extended from two opposite direction of the body. The two positioning pieces are configured for engaging in the through hole of the two side plates, and are rotatable between a first position, where the two positioning pieces is disengaged from the through holes of the side plates, and a second position, where the two positioning pieces is engaged in the through holes.

### BACKGROUND

1. Technical Field

The present disclosure relates to a server rack.

2. Description of Related Art

A server rack houses electronic equipment, such as data storage devices, and power supplies. The server rack includes a frame and a plurality of side plates installed in the frame. The electronic equipment is generally sensitive and important. Therefore, the security of the server rack is equally as important. Generally, each side plate is equipped with a lock to prevent it from being stolen.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of a server rack in accordance with an embodiment.

FIG. 2 is an exploded, isometric view of FIG. 1.

FIG. 3 is an isometric, partial view of FIG. 2.

FIG. 4 is an exploded, isometric view of two side plates and a maintaining member.

FIG. 5 is an enlarged view of an encircled portion V of FIG. 4.

FIG. 6 is an exploded, isometric view of a locking member of the server rack.

FIG. 7 is an isometric view of a latching member of the server rack.

FIG. 8 is an enlarged view of an encircled portion IIX of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

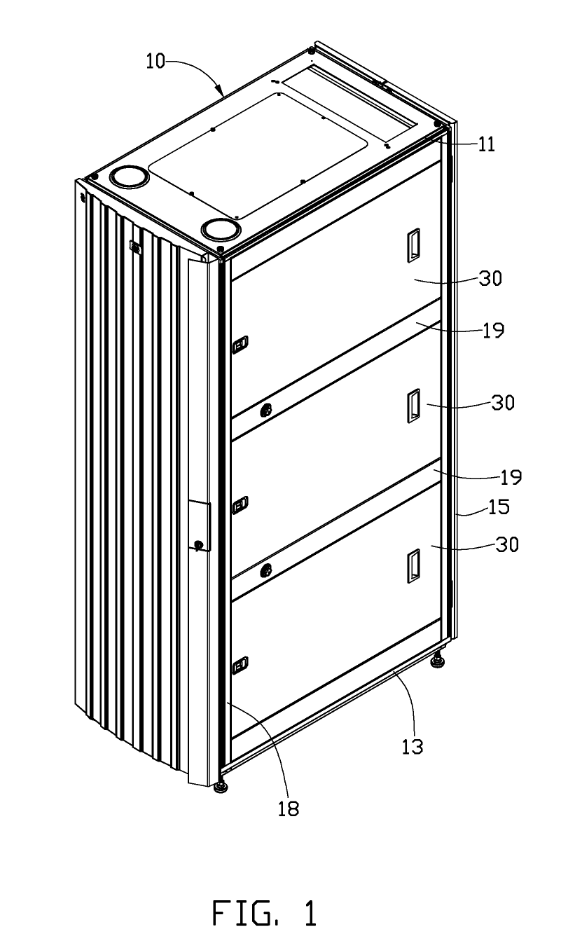

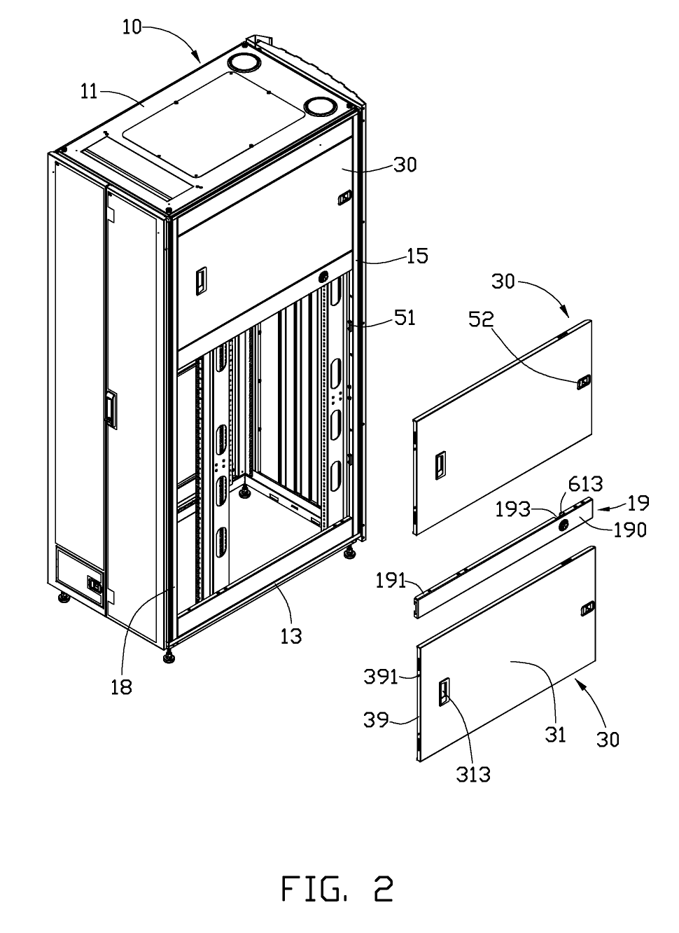

Referring to FIG. 1 and FIG. 2, a server rack in accordance with an embodiment includes a shell 10 and a plurality of side plates 30.

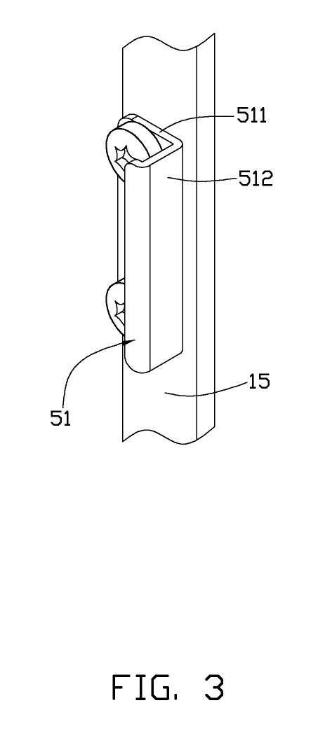

The shell 10 includes a top frame 11, a bottom frame 13, two first supports 15 and two second supports 18. The two first supports 15 and the second supports 18 are located between the top frame 11 and the bottom frame 13. A mounting member 51 is secured to the first support 15. Referring to FIG. 3, each mounting member 51 includes a first mounting portion 511 and a first latching portion 512 located on the first mounting portion 511. The first mounting portion 511 is secured to the first support 15. A plurality of positioning posts (not shown) is located on the second support 18.

A plurality of maintaining members 19 is located between one of the first supports 15 and one of the second supports 18 (only two maintaining members shown in the FIG. 1). Each maintaining member 19 includes a maintaining wall 190 and two maintaining pieces 191. The maintaining pieces 191 extend from two opposite edges of the maintaining wall 190. Each maintaining piece 191 defines a notch 193.

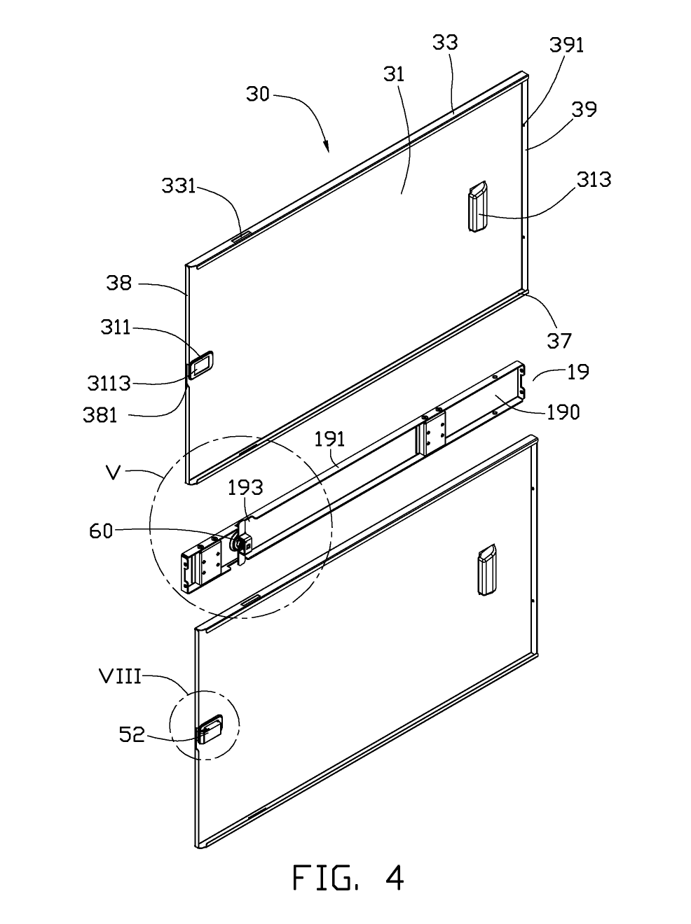

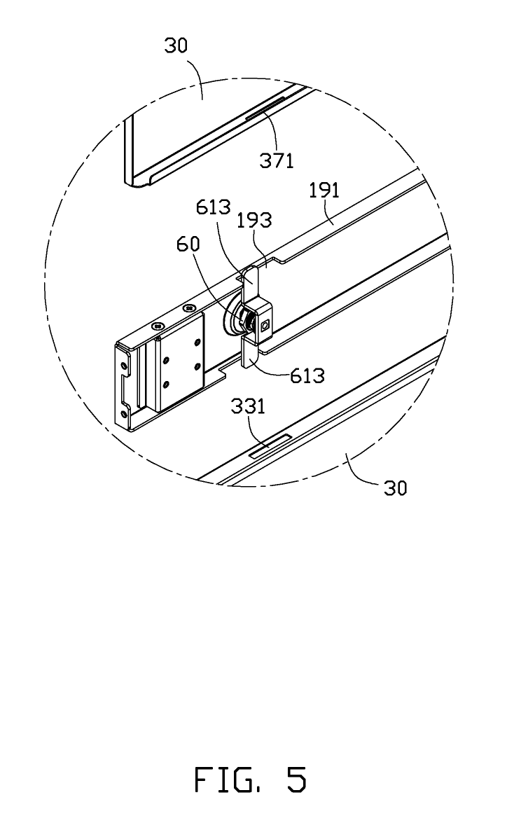

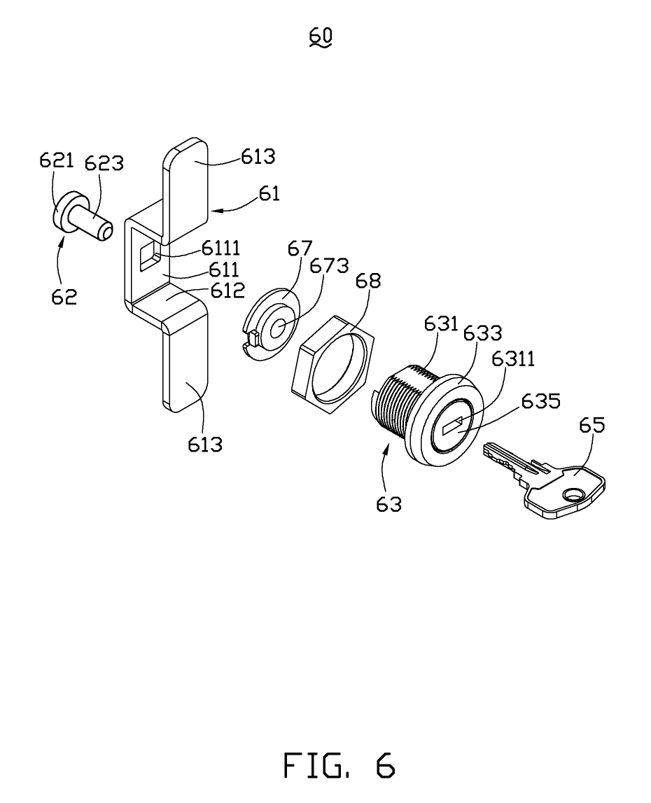

Referring to FIG. 4 to FIG. 6, a locking member 60 can be secured to the maintaining member 19 between the two notches 193. Each locking member 60 includes a locking tongue 61 and a latch 63. The latch 63 includes a mounting portion 631 and a connecting portion 633 for securing the mounting portion 631 to the maintaining member 19. The diameter of the mounting portion 631 is smaller than that of the connecting portion 633. The outer surface of the mounting portion 631 defines screw thread and a locking hole 6311. The mounting portion 631 is located in the maintaining wall 190 and the connecting portion 633 is located on the outer surface of the maintaining wall 190. A rotating portion 635 is rotatably installed to the connecting portion 633. An installing member 68, such as a nut, is secured to the mounting portion 631 to secure the latch 63 to the maintaining member 19.

The locking tongue 61 includes a main body 611 and two positioning pieces 613. The two positioning pieces 613 extend from two opposite edges of the main body 611 along two opposite directions. The main body 611 defines a positioning hole 6111. A positioning member 62, configured for securing the locking tongue 61, includes a first positioning portion 621 and a second positioning portion 623 located on the first positioning portion 621. In one embodiment, the diameter of the first positioning portion 621 is greater than that of the second positioning portion 623 and the width of the positioning hole 6111, and the diameter of the second positioning portion 623 is smaller than the width of the positioning hole 6111. A hoop 67 includes a limiting block (not shown) configured for being engaged in the positioning hole 6111. The hoop 67 defines a through hole 673 for receiving the second positioning portion 623 of the positioning member 62.

In assembly of the locking member 60, the mounting portion 631 of the latch 63 is engaged with the maintaining member 19, and the connecting portion 633 is located outside the maintaining wall 190. The hoop 67 is mounted to the latch 63. The limiting block is engaged in the positioning hole 6111, and the second positioning portion 623 is inserted in the through hole 673 to engage with the rotating portion 635. The locking tongue 61 is thereby secured to the latch 63. The locking tongue 61 can be rotate when the rotating portion 635 is rotated using tools, such as a key 65. The locking tongue 61 can be rotated between a first location and a second location. The two positioning pieces 613 of the locking tongue 61 are disengaged from the two notches 193 when the locking tongue 61 is in the first location; the two positioning pieces 613 are engaged in the two notches 193 when the locking tongue 61 is in the second location.

Each side plate 30 includes a plate body 31, a first flange 33, a second flange 37, a third flange 38 and a fourth flange 39 that extend respectively from a top edge, a bottom edge, a left edge and a right edge of the plate body 31. A knob 313 is located in the plate body 31 near the fourth flange 39. An installing wall 311 is located in the plate body 31 near the third flange 38. The installing wall 311 defines a mounting hole 3113. The first flange 33 and the second flange 37 respectively define a first limiting hole 331 and a second limiting hole 371, for receiving the locking tongue 61. A mounting notch 381 is defined in the third flange 38 near the mounting hole 3113. A plurality of positioning holes 391, configured for receiving the positioning post of the second support 18, are defined in the fourth flange 39.

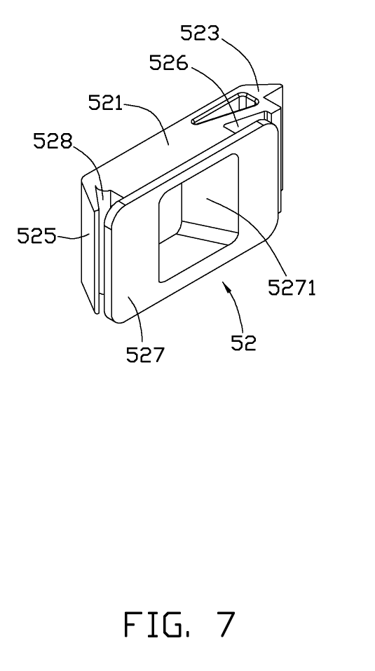

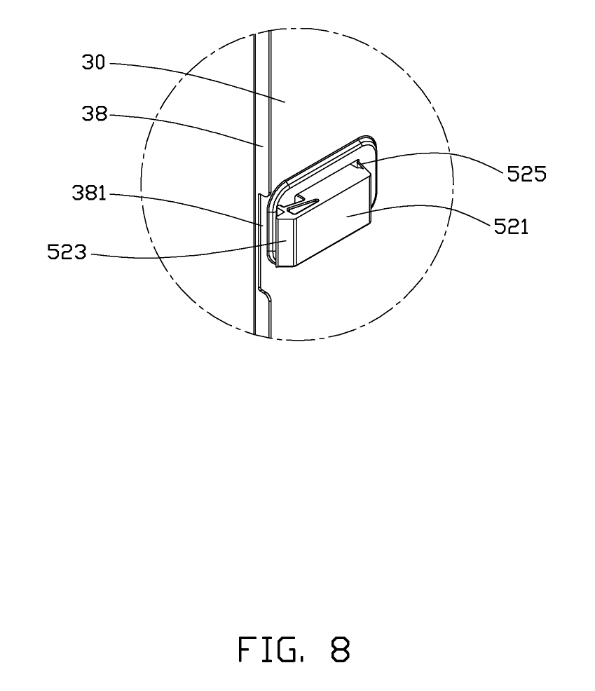

Referring to FIG. 7 and FIG. 8, a latching member 52, configured for being engaged in the mounting hole 3113, includes a body 521 and a limiting portion 527 located on the body 521. A second latching portion 523 is located in a first section of the body 521, and a resilient portion 525 is located in a second section of the body 521 opposite to the first section. In one embodiment, the resilient portion 525 extends from the body 521, and the second latching portion 523 includes a bevel surface. A first opening 526 is defined between the body 521 and the limiting portion 527, and a second opening 528 is defined between the body 521 and the resilient portion 525. The first opening 526 is adjacent to the second latching portion 523, and the second opening 528 is adjacent to the resilient portion 525. A groove 5271 is defined in the limiting portion 527 and extends to the body 521. In assembly of the latching member 52, the body 521 is engaged in the mounting hole 3113 of the side plate 30. A first edge of the mounting hole 3113 is engaged in the first opening 526. The resilient portion 525 abuts a second edge of the mounting hole 3113 opposite to the first edge. Thus, the latching member 52 is secured to the side plate 30 and can be slid relative to the side plate 30.

The latching member 52 is capable of sliding between a locked location and an unlocked location. In the locked location, the resilient portion 525 is elastically deformed at a minimum, and the second latching portion 523 is located out side the mounting notch 381. In the unlocked location, the resilient portion 525 is elastically deformed at maximum, and the second latching portion 523 is located inside the mounting notch 381 in the side plate 30.

In assembly of the side plate 30, the locking tongue 61 is located in the first location and the latching member 52 is located in the locked location. The fourth flange 39 of the side plate 30 abuts the second support 18 and the positioning post of the second support 18 is engaged in the positioning hole 391. The side plate 30 is rotated towards the first support 15, until the first latching portion 512 blocks the second latching portion 523. The first latching portion 512 slides the second latching portion 523 from the locked location to the unlocked location. The second latching portion 523 passes across the first latching portion 512. The third flange 38 abuts the first support 15. The second through hole 371 is aligned with the notch 193. The resilient portion 525 rebounds to slide the latching member 52 from the unlocked location to the locked location. The second latching portion 523 is engaged with the first latching portion 512. Thus, the side plate 30 is secured to the shell 10.

The rotating portion 635 of the latch 63 is rotated by the key 65, the locking tongue 61 is rotated from the first location to the second location. The positioning piece 613 is engaged in the second through hole 371 via the notch 193. The side plate 30 is thereby secured to the shell 10.

In disassembly of the side plate 30, the rotating portion 635 of the latch 63 is rotated by the key 65, the locking tongue 61 is rotated from the second location to the first location. The positioning piece 613 is disengaged from the second through hole 371. The latching member 52 is slid from the locked location to unlocked location. The second latching portion 523 is disengaged from the first latching portion 512. Thus, the side plate 30 can be removed from the shell 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A server rack comprising:
two side plates, each of the two side plates defining a through hole;
a shell, securing the two side plates, comprising a maintaining member located between the two side plates; and
a locking member secured to the maintaining member comprising a locking tongue, the locking tongue comprising a body and two positioning pieces extending from the body;
wherein the two positioning pieces are configured for engaging the two through holes.

2. The server rack of claim 1, wherein the maintaining member comprises a maintaining wall, and two maintaining pieces extend from two opposite edges of the maintaining wall.

3. The server rack of claim 2, wherein each maintaining piece defines a notch configured for receiving one of the two positioning pieces.

4. The server rack of claim 3, wherein each notch is aligned with one of the two through holes.

5. The server rack of claim 3, wherein the maintaining member is located between the two notches.

6. The server rack of claim 1, further comprising two latching members and two mounting members, each of the two side plates is secured to the shell by one of the two latching members and one of the two mounting members.

7. The server rack of claim 6, wherein each latching member is slidably secured to each side plate.

8. The server rack of claim 6, wherein each mounting member comprises a first latching portion and each latching member comprises a second latching portion configured for engaging with the first latching portion.

9. The server rack of claim 8, wherein each latching member is capable of sliding between a locked location, where the second latching portion is engaged with the first latching portion, and an unlocked location, where the second latching portion is disengaged from the first latching portion.

10. The server rack of claim 9, wherein each latching member comprises a resilient portion configured for sliding the latching member from the locked location to the unlocked location.

11. A server rack comprising:
two side plates, each of the two side plates defining a through hole;
a shell, securing the two side plates, comprising a maintaining member located between the two side plates; and
a locking member secured to the maintaining member comprising a locking tongue, the locking tongue comprising a body and two positioning pieces extended from the body;
wherein the two positioning pieces are rotatable between a first position, where the two positioning pieces are disengaged from the two through holes, and a second position, where the two positioning pieces are engaged in the two through holes.

12. The server rack of claim 11, wherein the maintaining member comprises a maintaining wall and two maintaining pieces extended from two opposite edges of the maintaining wall.

13. The server rack of claim 12, wherein each maintaining piece defines a notch configured for receiving one of the two positioning pieces.

14. The server rack of claim 13, wherein each notch is aligned with one of the two through holes.

15. The server rack of claim 13, wherein the maintaining member is located between the two notches.

16. The server rack of claim 11, further comprising two latching members and two mounting members, each of the two side plates is secured to the shell be one of the two latching members and one of the two mounting members.

17. The server rack of claim 16, wherein each latching member is slidably secured to each side plate.

18. The server rack of claim 16, wherein each mounting member comprises a first latching portion and each latching member comprises a second latching portion configured for engaging with the first latching portion.

19. The server rack of claim 18, wherein the latching member is capable of sliding between a locked location, where the second latching portion is engaged with the first latching portion, and an unlocked location, where the second latching portion is disengaged from the first latching portion.

20. The server rack of claim 19, wherein each latching member comprises a resilient portion configured for sliding the latching member from the locked location to the unlocked location.
